(19) United States
(12) Patent Application Publication
(10) Pub. No.: US 2014/0375391 A1
(43) Pub. Date: Dec. 25, 2014

(54) VOLTAGE CONTROLLED OSCILLATOR

(71) Applicant: SOONGSIL UNIVERSITY RESEARCH CONSORTIUM TECHNO-PARK, Seoul (KR)

(72) Inventors: Chang Kun PARK, Suwon (KR); Seong Woong CHO, Seoul (KR); Jae Hyuk YOON, Seoul (KR); Mi Lim LEE, Yangju-si (KR)

(21) Appl. No.: 14/308,727

(22) Filed: Jun. 19, 2014

(30) Foreign Application Priority Data
Jun. 21, 2013 (KR) 10-2013-0071645

(51) Int. Cl. H03B 5/02; H03B 5/12

(52) U.S. Cl. CPC H03B 5/02; H03B 5/1228
USPC 331/109

(57) ABSTRACT

Disclosed is a voltage controlled oscillator which includes a first transistor in which a first terminal is connected to a first power supply, a body is connected to a gate, and a first output signal is output through a second terminal; a second transistor that is cross-coupled to the first transistor in such a manner that a first terminal is connected to the first power supply, a body connected to the second terminal of the first transistor is connected to a gate, and a second terminal is connected to the body of the first transistor, and that outputs a second output signal having an opposite phase to that of the first output signal through the second terminal; and a resonance filter in which a first terminal is connected to the second terminal of the first transistor and a second terminal is connected to the second terminal of the second transistor.

### CROSS-REFERENCE TO RELATED APPLICATIONS

This application claims the priority of Korean Patent Application No. 10-2013-0071645 filed on Jun. 21, 2013, in the Korean Intellectual Property Office, the disclosure of which is incorporated herein by reference.

### BACKGROUND OF THE INVENTION

1. Field of the Invention

The present invention relates to a voltage controlled oscillator, and more particularly, to a voltage controlled oscillator capable of obtaining a relatively high gain value with the same power consumption by controlling a body effect of a power amplifier of the voltage controlled oscillator.

2. Description of the Related Art

In general, a voltage controlled oscillator is a device that allows a desired oscillation frequency to be output by using a voltage applied from the outside. A voltage controlled oscillator that uses transistors which are cross-coupled to each other is disclosed as a related technology.

FIG. 1 illustrates a cross-coupled LC voltage controlled oscillator according to the related art. In general, the LC voltage controlled oscillator forms an arbitrary feedback loop in order for oscillation when the voltage controlled oscillator using a LC resonance filter is designed, and a differential voltage controlled oscillator satisfies an oscillation condition by connecting an input and an output to each other.

Referring to FIG. 1, a drain signal of a counterpart transistor is input to a gate of a transistor, and the signal is amplified and is output through a drain. Such a process is repeated. The structure of FIG. 1 autonomously oscillates without a separate AC input signal.

However, there is generally a limitation that the body of the transistor according to the related art is used to constantly maintain a threshold voltage. An undesired change of the threshold voltage causes a distortion of a signal to reduce linearity. In some cases, degradation in performance of a circuit such as an occurrence of a leakage current may be caused. The threshold voltage is changed by a parameter of a manufacturing process, a physical parameter of a transistor, and a voltage difference between the source and the body. Since it is difficult to control the parameter of the manufacturing process and the physical parameter of the transistor, it is necessary to minimize influence of the parameters. For this reason, influence by the parameter of the manufacturing process and physical parameter is removed to maintain a unique threshold voltage of the transistor by connecting the body and the source.

However, when a circuit is actually implemented, in order to maintain the threshold voltage, there is a limitation on performance. In the related art to which a triple-well process is not applied, it is difficult to maintain the unique threshold voltage by connecting the source and the body. When a cascode structure and a structure similar to the cascode structure are applied, since MOSFETs share a substrate, bodies of the MOSFETs need to be connected to each other. At this time, when the MOSFETs are PMOSs, the bodies need to be connected to a power supply voltage, and when the MOSFETs are NMOSs, the bodies need to be connected to a ground. For this reason, the bodies and the sources may be separated, and degradation in performance such as an increase of a Ron resistance may be caused due to a rise of the threshold voltage.

As another method, in order to prevent the threshold voltage from being increased, when the bodies are connected to the sources without sharing the substrate, a current flows through a resistance component of the substrate due to a voltage difference between the bodies, so that various problems such as heating, noise occurrence and signal leakage may be caused.

In the related art to which the triple-well process is applied, the MOSFETs may be separated by a triple-well to connect the bodies and the sources. Accordingly, it is possible to prevent a change of the threshold voltage by a substrate effect. As a result, a design area is increased, but it is possible to prevent performance from being degraded.

When the sources and the bodies are connected in a DC manner as in the related art, the threshold voltage of the transistor is fixed to one value. Accordingly, there is a characteristic in that a maximum output power or a gain of the corresponding amplifier is proportion to a size of the transistor.

As another related art, there is a technique in which biases of the source and the body are separated and the body bias is increased. In such a case, it is expected that the threshold voltage is decreased by a body-bias effect. In this case, as compared to the related art in which the sources and the bodies are connected, it is possible to obtain a relatively high gain and a high maximum output power with the same transistor. However, in the related art, in order to obtain the high gain and the high maximum output power, a high DC current is used by setting the body bias to be high, so that the entire power using efficiency of the amplifier may be decreased, and the leakage current may be increased.

A technology which is a background of the present invention is disclosed in Korean Patent Publication No. 2009-0040640 (published on Apr. 27, 2009).

### SUMMARY OF THE INVENTION

An aspect of the present invention provides a voltage controlled oscillator capable of having a high gain with the same power consumption.

According to an aspect of the present invention, there is provided a voltage controlled oscillator including a first transistor in which a first terminal is connected to a first power supply, a body is connected to a gate, and a first output signal is output through a second terminal; a second transistor that is cross-coupled to the first transistor in such a manner that a first terminal is connected to the first power supply, a body connected to the second terminal of the first transistor is connected to a gate, and a second terminal is connected to the body of the first transistor, and that outputs a second output signal having an opposite phase to that of the first output signal through the second terminal; and a resonance filter in which a first terminal is connected to the second terminal of the first transistor and a second terminal is connected to the second terminal of the second transistor.

The voltage controlled oscillator may further include DC power supplies that are connected to the bodies of the first and second transistors.

The voltage controlled oscillator may further include a first capacitor in which a first terminal is connected to the gate of the first transistor and a second terminal is connected to the DC power supply; and a second capacitor in which a first terminal is connected to the gate of the second transistor and a second terminal is connected to the DC power supply.

The second terminals of the first and second transistors may be connected to a second power supply.

The first power supply may be a ground power supply.

According to another aspect of the present invention, there is provided a voltage controlled oscillator including a first transistor in which a first terminal is connected to a first power supply and a first output signal is output through a second terminal; a second transistor that is cross-coupled to the first transistor in such a manner that a first terminal is connected to the first power supply, a gate is connected to the second terminal of the first transistor, and a second terminal is connected to the gate of the first transistor, and that outputs a second output signal having an opposite phase to that of the first output signal through the second terminal; a transformer in which a first terminal of a primary side is connected to the second terminal of the first transistor, a second terminal of the primary side is connected to the second terminal of the second transistor, a first terminal of a secondary side is connected to a body of the first transistor, and a second terminal of the secondary side is connected to a body of the second transistor; and a capacitor in which a first terminal is connected to the second terminal of the first transistor and a second terminal is connected to the second terminal of the second transistor.

A second power supply may be connected to the primary side of the transformer.

The voltage controlled oscillator may further include a DC power supply that is connected to the secondary side of the transformer.

The first power supply may be a ground power supply.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 illustrates a cross-coupled LC voltage controlled oscillator according to the related art;

FIG. 2 is a diagram for describing a voltage controlled oscillator according to an exemplary embodiment of the present invention;

FIG. 3 is a diagram illustrating a structure of a voltage controlled oscillator according to a first exemplary embodiment of the present invention;

FIG. 4 illustrates an example where a body biasing network in FIG. 3 is implemented by capacitors;

FIG. 5 is a diagram illustrating a structure of a voltage controlled oscillator according to a second exemplary embodiment of the present invention; and

FIG. 6 is a diagram illustrating a structure in which a diagram illustrating a case where PMOSs are used in the voltage controlled oscillator according to the first exemplary embodiment of the present invention.

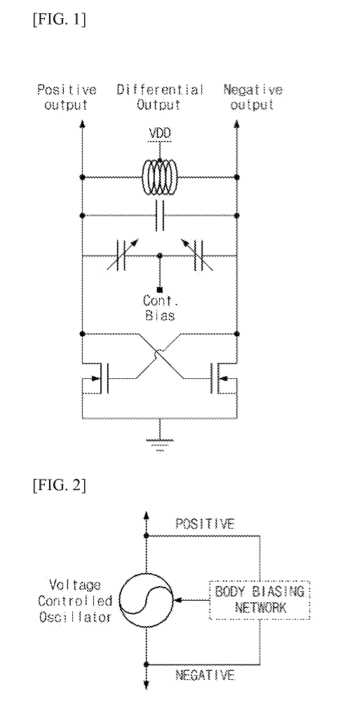

### DETAILED DESCRIPTION OF THE PREFERRED EMBODIMENT

Exemplary embodiments of the present invention will now be described in detail with reference to the accompanying drawings.

As set forth above, according to exemplary embodiments of the invention, since signals having the same phase as that of a gate and DC voltages are applied through bodies of transistors to adjust a threshold voltage, it is possible to obtain a relatively high gain with the same power consumption as compared to the related art, and since a feedback loop is additionally formed, it is possible to reduce an oscillating time.

Hereinafter, exemplary embodiments of the present invention will be described in detail with reference to the accompanying drawings to allow those skilled in the art to easily implement the exemplary embodiments. However, the present invention can be implemented in various manners, and is not limited to the exemplary embodiments. Parts that are not related to the description are omitted to clearly describe the present invention, and like parts are assigned like reference numerals throughout the specification.

Throughout the specification, when one part is “connected” to another part, the one part may be “directly connected” to another part, or may be “electrically connected” to another part via a third part. Further, unless the context clearly indicates otherwise, when one part “includes” other components, it means that the one part excludes the other components but may further include the other components.

In addition, throughout the specification, the expression ‘a voltage is maintained’ means that even though a potential difference between two predetermined points is changed with time, the change value is within an allowable range, or means that the change is caused by a parasitic component which is not considered in design by those skilled in the art. Further, since a threshold voltage of a semiconductor device (a transistor or a diode) is very lower than a discharge voltage, the threshold voltage is regarded as 0 V, and is approximated.

FIG. 2 is a diagram for describing a voltage controlled oscillator according to an exemplary embodiment of the present invention. The voltage controlled oscillator needs a low-power operation, a low-phase noise, and a high gain. In order to overcome such a limitation, in the exemplary embodiment of the present invention, the phase noise is controlled so as not to be higher by using a body effect of a transistor through a body biasing network, and it is possible to obtain a relatively high gain value with the same power consumption.

Hereinafter, for the sake of convenience in description, it will be described that a transistor of the voltage controlled oscillator according to the exemplary embodiment of the present invention is an NMOS (N-Channel MOSFET), but the transistor may be a PMOS (P-Channel MOSFET).

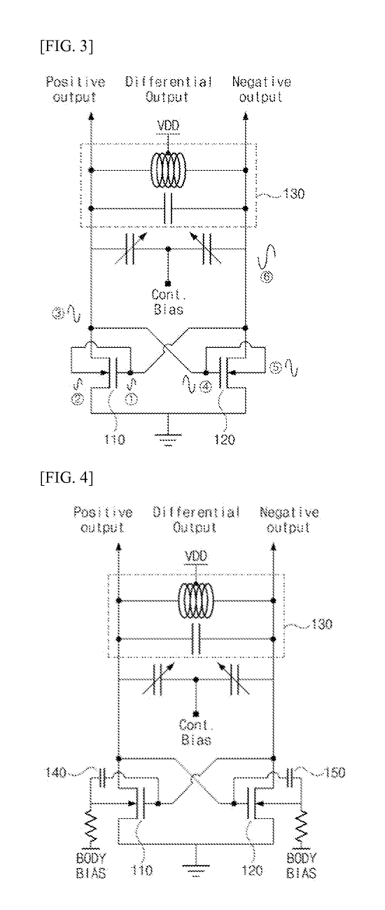

FIG. 3 is a diagram illustrating a structure of a voltage controlled oscillator according to a first exemplary embodiment of the present invention. The voltage controlled oscillator of FIG. 3 has a differential structure. Since a body of a transistor is connected to a gate thereof, a signal having the same phase as that of V_{GS} (a voltage between a gate and a source) of the transistor is input to the body.

More specifically, the voltage controlled oscillator illustrated in FIG. 3 includes a first transistor 110, a second transistor 120, and a resonance filter 130. A first terminal of the first transistor 110 is connected to a first power supply (for example, GND), a body is connected to a gate, and a first output signal (a positive output) is output through a second terminal

The second transistor 120 is cross-coupled to the first transistor in such a manner that a first terminal is connected to the first power supply (for example, GND), a body connected to the second terminal of the first transistor 110 is connected to a gate, and a second terminal is connected to the body of the first transistor 110. The second transistor 120 outputs a second output signal (a negative output) having an opposite phase to that of the first output signal through the second terminal

The second terminals of the first transistor 110 and the second transistor 120 are connected to a second power supply (for example, VDD) higher than the first power supply through the resonance filter 130. The resonance filter 130 has a structure of a LC resonance filter, a first terminal thereof is connected to the second terminal of the first transistor 110, and a second terminal thereof is connected to the second terminal of the second transistor 120.

In the aforementioned configuration according to the first exemplary embodiment illustrated in FIG. 3, a signal change of the voltage controlled oscillator will be described in detail below. A negative output signal output from a drain of the second transistor 120 is simultaneously input to the gate and the body of the first transistor 110 (\textcircled{1} and \textcircled{2}).

Further, a positive output signal having an opposite phase to that of the signal input to the gate of the first transistor 110 is amplified and is output through the drain of the first transistor 110 (\textcircled{3}). At this time, since the signal that is previously input to the gate of the first transistor 110 has the same phase as the signal input to the body, a signal amplifying effect through the first transistor 110 is further increased by the signal having the same phase which is input to the body, and power efficiency is increased.

Furthermore, a positive output signal output from the drain of the first transistor 110 is simultaneously input to the gate and the body of the second transistor (\textcircled{4} and \textcircled{5}). Moreover, a negative output signal having an opposite phase to that of the signal input to the gate of the second transistor 120 is amplified and is output through the drain of the second transistor 120(\textcircled{6}). At this time, since the signal input to the gate of the second transistor 120 has the same phase as the signal input to the body, a signal amplifying effect through the second transistor 120 is further increased by the signal having the same phase which is input to the body, and power efficiency is increased.

FIG. 4 illustrates an example where the body biasing network of FIG. 3 is implemented using a capacitor. Similarly to FIG. 3, since the body of the transistor is connected to the gate in FIG. 4, the signal having the same phase as that of the V_{GS} (a voltage between the gate and the source) of the transistor is input to the body, and a DC voltage (a body bias) is also applied to the body.

More specifically, according to the configuration of FIG. 4, DC power supplies for applying a DC voltage (a body bias) are connected to the bodies of the first transistor 110 and the second transistor 120. In addition, capacitors 140 and 150 are connected between the DC power supplies and the gates of the transistors.

A first terminal of the first capacitor 140 is connected to the gate of the first transistor 110, and a second terminal thereof is connected to the DC power supply. A first terminal of the second capacitor 150 is connected to the gate of the second transistor 120, and a second terminal thereof is connected to the DC power supply.

The capacitors 140 and 150 correspond to DC block caps, and serve to prevent the DC voltages (body biases) that are directly applied to the bodies from being introduced to the gates of the transistors 110 and 120. In the exemplary embodiment of FIG. 4, since the DC voltages (body biases) and the capacitors are used, an oscillating start time becomes fast, so that an oscillating time becomes short.

According to the exemplary embodiment of the present invention described above, the signals according to the operation phases of the power amplifiers (MOSFETs) of the voltage controlled oscillator and the DC bias voltages are applied to the body to appropriately change a threshold voltage, so that an amplifying limitation in the related art is overcome. Further, a feedback loop is further provided, so that the oscillating time becomes short. In addition, since the signal having the same phase as that of the V_{GS} is simply feedback to the body of the corresponding transistor, it is possible to simply implement the voltage controlled oscillator without connecting an additional device thereto.

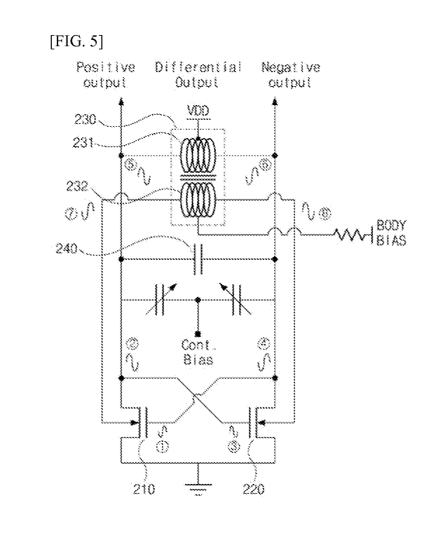

FIG. 5 is a diagram illustrating a structure of a voltage controlled oscillator according to a second exemplary embodiment of the present invention. In FIG. 5, bodies of transistors are connected to a secondary side 232 of a transformer 230. In such a configuration, the body biasing network is achieved. Accordingly, a signal having the same phase as that of V_{GS} (a voltage between a gate and a source) of a transistor is input to a body of the transistor.

More specifically, the voltage controlled oscillator illustrated in FIG. 5 includes a first transistor 210, a second transistor 220, a transformer 230, and a capacitor 240.

A first terminal of the first transistor 210 is connected to a first power supply (for example, GND), and a first output signal (a positive output) is output through a second terminal thereof.

The second transistor 220 is cross-coupled to the first transistor 210 in such a manner that a first terminal is connected to the first power supply (for example, GND), a gate is connected to the second terminal of the first transistor 210, and a second terminal is connected to the gate of the first transistor 210. The second transistor 220 outputs a second output signal (a negative output) having an opposite phase to that of the first output signal through the second terminal.

The transformer 230 includes a primary side 231 and the secondary side 232. A first terminal of the primary side 231 is connected to the second terminal of the first transistor 210, and a second terminal thereof is connected to the second terminal of the second transistor 220. A first terminal of the secondary side 232 is connected to the body of the first transistor 210, and a second terminal thereof is connected to the body of the second transistor 220. Further, a second power supply (for example, VDD) higher than the first power supply is connected to the primary side 231 of the transformer 230, and a power supply voltage that applies a DC voltage (a body bias) to a body is connected to the secondary side 232.

A first terminal of the capacitor 240 is connected to the second terminal of the first transistor 210, and a second terminal thereof is connected to the second terminal of the second transistor 220. In such a configuration, the capacitor 240 and the transformer 230 serve as the resonance filter structure.

In the aforementioned configuration according to the second exemplary embodiment illustrated in FIG. 5, a signal change of the voltage controlled oscillator will be described in more detail below.

A negative output signal output from a drain of the second transistor 220 is input to the gate of the first transistor 210 (\textcircled{1}). Furthermore, a positive output signal having an opposite phase to that of the signal input to the gate of the first transistor is amplified and is output through a drain of the first transistor 210 (\textcircled{2}). Similarly, the signal output from the drain of the first transistor 210 is input to the gate of the second transistor 220 (\textcircled{3}). Moreover, a negative output signal having an opposite phase to that of the signal input to the gate of the second transistor is amplified and is output through the drain of the second transistor 220 (\textcircled{4}).

The signal that is output through the drain of the first transistor 210 in the previous process \textcircled{2} is input to the first terminal of the primary side 231 of the transformer 230 (\textcircled{5}), and the signal having the opposite phase which is output through the drain of the second transistor 220 in the previous process \textcircled{4} is input to the second terminal of the primary side 231 (\textcircled{6}).

The signal having the opposite phase to that of the signal input to the first terminal of the primary side 231 is output through the first terminal of the secondary side 232, and is introduced to the body of the first transistor 210 (\textcircled{7}). At this time, since the signal introduced to the body of the first transistor 210 has the same phase as that of the signal input to the gate in the previous process \textcircled{1}, a signal amplifying effect through the first transistor 210 is further increased by the signal having the same phase which is input to the body, and power efficiency is increased.

In contrast, the signal having the opposite phase to that of the signal input to the second terminal of the primary side 231 is output through the second terminal of the secondary side 232, and is introduced to the body of the second transistor 220 (\textcircled{8}). At this time, since the signal introduced to the body of the second transistor 220 has the same phase as the signal input to the gate in the previous process \textcircled{3}, a signal amplifying effect through the second transistor 220 is further increased by the signal having the same phase which is input to the body, and power efficiency is increased.

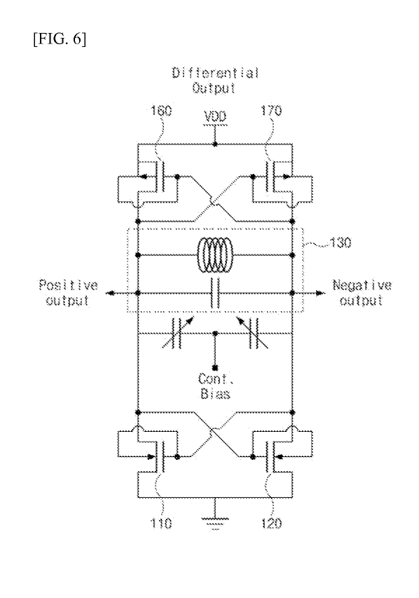

FIG. 6 is a diagram illustrating a structure of an oscillator in which PMOSs are additionally used in the voltage controlled oscillator according to the first exemplary embodiment of the present invention. FIG. 6 illustrates a configuration in which the PMOSs are additionally used in the voltage controlled oscillator of FIG. 3 using the NMPSs, and illustrates the configuration further includes a third transistor 160 and a fourth transistor 170 which are the PMOSs at an upper side.

Here, the third transistor 160 and the fourth transistor 170 are cross-coupled to each other, and have a structure in which bodies and gates of the transistors are connected to each other. In such a configuration, amplifying efficiency is further increased. As described above, when the third transistor 160 and the fourth transistor 170 are further used at output terminals of the first transistor 210 and the second transistor 220, a size of the circuit becomes larger than the circuit of FIG. 3, but it is possible to obtain a higher gain.

In accordance with the above-stated voltage controlled oscillator according to the present invention, it is possible to obtain a high gain with the same power consumption. Further, it is possible to apply the voltage controlled oscillator to most amplifiers through various methods using a passive device.

While the present invention has been described in connection with the exemplary embodiments, the exemplary embodiments are merely examples. It will be apparent to those skilled in the art that modifications and equivalents to the exemplary embodiments can be made. Therefore, the technical scope of the present invention should be decided by the technical spirit of the appended claims.

What is claimed is:

1. A voltage controlled oscillator comprising:
a first transistor in which a first terminal is connected to a first power supply, a body is connected to a gate, and a first output signal is output through a second terminal;
a second transistor that is cross-coupled to the first transistor in such a manner that a first terminal is connected to the first power supply, a body connected to the second terminal of the first transistor is connected to a gate, and a second terminal is connected to the body of the first transistor, and that outputs a second output signal having an opposite phase to that of the first output signal through the second terminal; and
a resonance filter in which a first terminal is connected to the second terminal of the first transistor and a second terminal is connected to the second terminal of the second transistor.

2. The voltage controlled oscillator of claim 1, further comprising:
DC power supplies that are connected to the bodies of the first and second transistors.

3. The voltage controlled oscillator of claim 2, further comprising:
a first capacitor in which a first terminal is connected to the gate of the first transistor and a second terminal is connected to the DC power supply; and
a second capacitor in which a first terminal is connected to the gate of the second transistor and a second terminal is connected to the DC power supply.

4. The voltage controlled oscillator of claim 1, wherein the second terminals of the first and second transistors are connected to a second power supply.

5. The voltage controlled oscillator of claim 4, wherein the first power supply is a ground power supply.

6. A voltage controlled oscillator comprising:
a first transistor in which a first terminal is connected to a first power supply and a first output signal is output through a second terminal;
a second transistor that is cross-coupled to the first transistor in such a manner that a first terminal is connected to the first power supply, a gate is connected to the second terminal of the first transistor, and a second terminal is connected to the gate of the first transistor, and that outputs a second output signal having an opposite phase to that of the first output signal through the second terminal;
a transformer in which a first terminal of a primary side is connected to the second terminal of the first transistor, a second terminal of the primary side is connected to the second terminal of the second transistor, a first terminal of a secondary side is connected to a body of the first transistor, and a second terminal of the secondary side is connected to a body of the second transistor; and
a capacitor in which a first terminal is connected to the second terminal of the first transistor and a second terminal is connected to the second terminal of the second transistor.

7. The voltage controlled oscillator of claim 6, wherein a second power supply is connected to the primary side of the transformer.

8. The voltage controlled oscillator of claim 7, further comprising:
a DC power supply that is connected to the secondary side of the transformer.

9. The voltage controlled oscillator of claim 6, wherein the first power supply is a ground power supply.
